(19) United States
(12) Patent Application Publication
(10) Pub. No.: US 2010/0224933 A1
(43) Pub. Date: Sep. 9, 2010

(54) Semiconductor device

(76) Inventors: Hisashi Hasegawa, Chiba-shi (JP); Hideo Yoshino, Chiba-shi (JP)

Correspondence Address: BRUCE L. ADAMS, ESQ;ADAMS & WILKS, 17 Battery Place - Suite 1231, New York, NY, 10004, US

(21) Appl. No.: 12/658,390

(22) Filed: Feb. 5, 2010

(30) Foreign Application Priority Data
Feb. 6, 2009 (JP) 2009-026502
Nov. 18, 2009 (JP) 2009-263379

(51) Int. Cl. H01L 29/78

(52) U.S. Cl. 257/339; 257/E29.256

(57) ABSTRACT

Provided is a semiconductor device including an N-channel high-voltage MOS transistor, in which wiring metal connected to a drain region is laid above a boundary portion between an oxide film formed by LOCOS process or the like on a low impurity concentration region and a high impurity concentration region forming the drain region, to thereby alleviate an electric field concentration at the boundary portion which is a contact portion between the low impurity concentration region and the high impurity concentration region by an electric field generated from the wiring metal toward a semiconductor substrate.

### BACKGROUND OF THE INVENTION

1. Field of the Invention

The present invention relates to a semiconductor device including a semiconductor element such as an N-channel high-voltage metal oxide semiconductor (MOS) transistor.

2. Description of the Related Art

Elements used in a semiconductor device include a low-voltage element which has a low operating voltage, and a high-voltage element which may be used even when a power supply voltage is high, depending on the respective use thereof. For example, a high-voltage element is used only in a section which directly handles a voltage applied to and output from the semiconductor device, while a low-voltage element is used in a section which performs internal signal processing. The low-voltage element occupies a smaller area than the high-voltage element. Accordingly, the high-voltage element is used only in a section which determines the performance specification of the integrated circuit and is difficult to modify, such as a section relating to voltages exchanged with outside, and the low-voltage element is used in a section for performing the internal processing, which allows the reduction in the area of the semiconductor device and the manufacturing cost thereof.

FIG. 2 is a schematic cross-sectional view illustrating an example of a semiconductor device which includes such low-voltage MOS transistor and high-voltage MOS transistor.

A low-voltage N-channel MOS transistor (hereinafter, referred to as NMOS) 202 includes a gate insulating film 5, a gate electrode 7 formed directly above the gate insulating film 5, and source and drain regions formed on both sides thereof. The source and drain regions include a second N-type high impurity concentration region 9 of low resistance for connection to wiring metal, and a second N-type low impurity concentration region 10 for alleviating electric field intensity.

On the other hand, a high-voltage N-channel MOS transistor 201 includes the gate insulating film 5, the gate electrode 7 formed directly above the gate insulating film 5, and source and drain regions formed on both sides thereof. The source and drain regions include first N-type high impurity concentration regions 2 and 3 and a first N-type low impurity concentration region 4, and the high-voltage N-channel MOS transistor 201 further includes an oxide film 6, which is larger in thickness than the gate insulating film 5, formed on the first N-type low impurity concentration region 4. The thick oxide film has an effect of alleviating the electric field intensity between the gate electrode and the drain. The above-mentioned drain structure is employed in a case where the drain withstand voltage needs to be 20 V or more, and the withstand voltage is adjusted mainly by varying the length and the concentration of the N-type low impurity concentration region of the drain, to thereby suppress a surface breakdown due to an avalanche breakdown, or a breakdown caused by a parasitic bipolar transistor (parasitic bipolar breakdown). Further, in a case where the gate of the high-voltage NMOS is also applied with a voltage which is larger than the voltage applied to the low-voltage NMOS, the thickness of the gate insulating film is generally increased only for the portion corresponding to the high-voltage NMOS according to the voltage.

The first N-type high impurity concentration regions 2 and 3 of the high-voltage NMOS are generally formed through the same process for forming the N-type high impurity concentration region 9 of the low-voltage NMOS for the purpose of reducing process cost, and arsenic or antimony is used as the impurity to be implanted therein.

Further, the first N-type low impurity concentration region 4 is generally used in combination with a channel stop structure formed in an element isolation region, thereby reducing process cost. The first N-type low impurity concentration region 4 accordingly has an oxide film obtained through a LOCOS process formed thereon, and the concentration of the first N-type low impurity concentration region 4 is adjusted to a value that prevents inversion due to a potential of the wiring metal formed on the LOCOS oxide film. In general, in a case where the high-voltage NMOS is less frequently used in the semiconductor integrated circuit, limitations are imposed on the high-voltage NMOS in terms of structure for reducing cost as described above, and the element has to be designed under the limiting conditions.

The above-mentioned structure of the high-voltage NMOS is disclosed in JP 06-350084 A and the like.

However, in the high-voltage MOS transistor, in addition to the conventionally known breakdown such as the above-mentioned surface breakdown and parasitic bipolar breakdown, a breakdown phenomenon occurs in the vicinity of the drain when a gate voltage is gradually increased during a saturation operation in which a drain voltage and the gate voltage are set to high voltage.

### SUMMARY OF THE INVENTION

It is an object of the present invention to provide a simpler method capable of suppressing a breakdown of an element when saturation operation is performed, in particular, when a voltage of a gate electrode is increased, to thereby attain a high withstand voltage of the element.

In order to attain the above-mentioned object, the following configurations are employed. That is, a semiconductor device according to the present invention includes an N-channel high-voltage metal oxide semiconductor (MOS) transistor, the N-channel high-voltage MOS transistor including on a semiconductor substrate: a gate insulating film; a gate electrode made of polysilicon; source and drain regions each including an N-type high impurity concentration region and an N-type low impurity concentration region formed between the gate insulating film and the N-type high impurity concentration region; an insulating film formed on the N-type low impurity concentration region and formed to be in contact with the N-type high impurity concentration region, the insulating film being larger in thickness than the gate insulating film; and a wiring metal thin film connected to the N-type high impurity concentration region of the drain region through a first contact hole, in which the wiring metal thin film is laid above a boundary portion between the insulating film which is larger in thickness than the gate insulating film and the N-type high impurity concentration region of the drain region, and is further formed so as to extend above the N-type low impurity concentration region of the drain region.

Further, in the semiconductor device described above, the insulating film includes a bird's beak portion in part thereof, the insulating film being formed in contact with the N-type high impurity concentration region, and the wiring metal thin film is formed above the bird's beak portion.

Still further, in the semiconductor device described above, the wiring metal thin film is formed to extend at least to 0.5 μm from the boundary portion between the insulating film which is larger in thickness than the gate insulating film and the N-type high impurity concentration region of the drain region so as to extend above the N-type low impurity concentration region of the drain region.

Still further, in the semiconductor device described above, the insulating film includes a bird's beak portion in part thereof, the insulating film being formed in contact with the N-type high impurity concentration region of the drain region, and the semiconductor device further includes a second contact hole different from the first contact hole, the second contact hole being formed above the bird's beak portion and embedded with the wiring metal thin film.

According to the present invention, the N-channel high-voltage MOS transistor is configured such that the wiring metal connected to the drain region is laid above the boundary portion between the oxide film formed by LOCOS process or the like of the low impurity concentration region and the high impurity concentration region forming the drain region. Accordingly, an electric field concentration at the boundary portion which is the contact portion between the low impurity concentration region and the high impurity concentration region may be alleviated by the electric field generated from the wiring metal toward the semiconductor substrate. Consequently, it is possible to suppress an impact ionization which occurs when a high gate voltage is applied during saturation operation of the NMOS transistor, with the result that a high withstand voltage thereof is attained.

### BRIEF DESCRIPTION OF THE DRAWINGS

In the accompanying drawings:

FIG. 1A is a schematic cross-sectional view illustrating a high-voltage NMOS transistor according to the present invention;

FIG. 1B is a schematic plan view illustrating a high-voltage NMOS transistor according to the present invention;

FIG. 2 is a schematic cross-sectional view illustrating examples of a conventional low-voltage NMOS transistor and a conventional high-voltage NMOS transistor;

FIG. 3 is a graph illustrating gate voltage-substrate current characteristics during a saturation operation of a general high-voltage NMOS transistor;

FIG. 4 is a graph illustrating drain voltage-drain current characteristics during the saturation operation of the high-voltage NMOS transistor according to the present invention;

FIG. 5A is a schematic cross-sectional view illustrating a high-voltage NMOS transistor with a conventional structure;

FIG. 5B is a schematic plan view illustrating a high-voltage NMOS transistor with a conventional structure;

FIG. 6 is a graph illustrating drain voltage-drain current characteristics during the saturation operation of the high-voltage NMOS transistor with the conventional structure; and

FIG. 7A is a schematic cross-sectional view illustrating another aspect of the high-voltage NMOS transistor according to the present invention;

FIG. 7B is a schematic plan view illustrating another aspect of the high-voltage NMOS transistor according to the present invention.

### DETAILED DESCRIPTION OF THE PREFERRED EMBODIMENT

Hereinafter, an embodiment of the present invention is described with reference to the drawings.

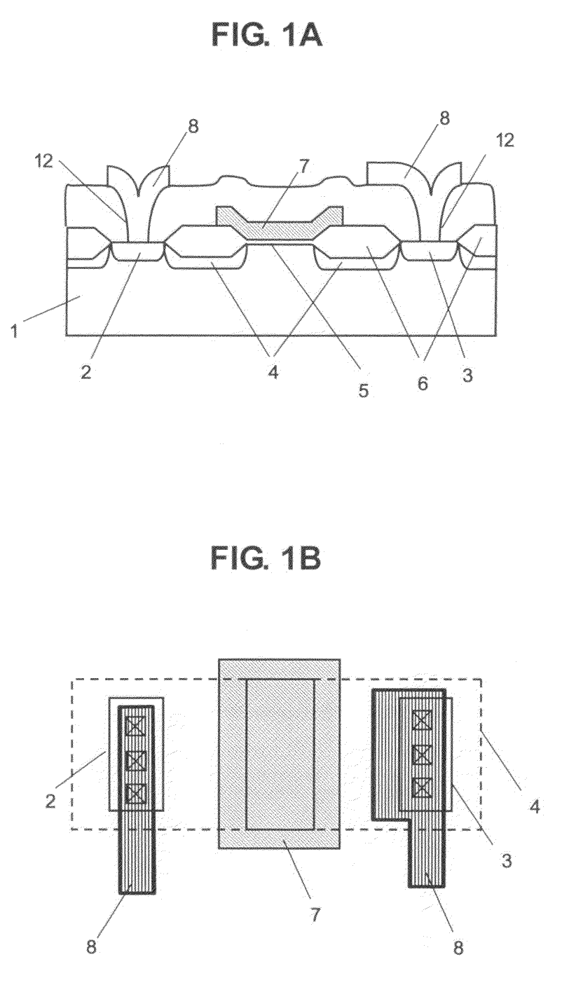

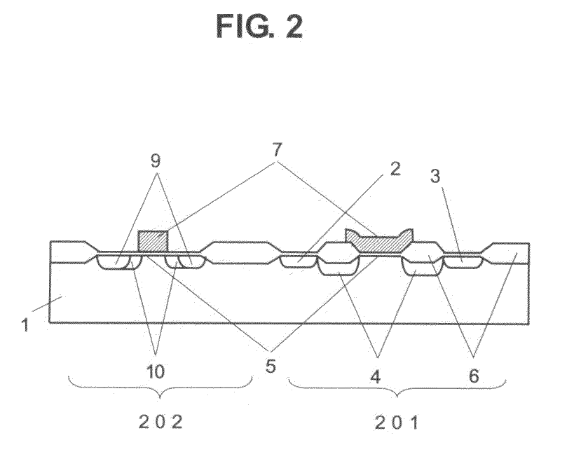

FIGS. 1A and 1B are a schematic cross-sectional view and a schematic plan view, respectively, each illustrating a high-voltage N-channel metal oxide semiconductor (NMOS) transistor according to the embodiment of the present invention. The high-voltage NMOS transistor includes a gate insulating film 5 formed on a surface of a P-type semiconductor substrate 1 or P-type well, a LOCOS oxide film 6 which is an insulating film formed contiguously to the gate insulating film 5 and has a thickness larger than that of the gate insulating film, a gate electrode 7 formed so as to extend across the gate insulating film 5 and portions of the LOCOS oxide film 6 close to the gate insulating film, an N-type low impurity concentration region 4 formed below the LOCOS oxide film 6, N-type high impurity concentration regions 2 and 3, each formed next to the N-type low impurity concentration region 4, and wiring metal 8 connected to the high impurity concentration regions 2 and 3 through contact holes 12 formed in an interlayer insulating film.

The high-voltage NMOS transistor according to this embodiment has a structure as follows. The LOCOS oxide film 6 includes a bird's beak portion at which the thickness thereof changes. The bird's beak portion starts from a boundary portion between the high impurity concentration region 3, which serves as the drain region of the high-voltage NMOS transistor, and the low impurity concentration region 4. The wiring metal 8 connected to the drain region is laid above the LOCOS oxide film 6 at the bird's beak portion. Further, the wiring metal 8 extends even above the low impurity concentration region 4 to be laid thereabove. On the other hand, in the high impurity concentration region 2 on a source region side, it is unnecessary to lay the wiring metal 8 over the corresponding region so as to achieve the effect of the present invention. Further, in this embodiment, the LOCOS oxide film 6 is also formed below the gate electrode on the source region side, which is not essential. It may be omitted in order to reduce the occupying area of the element.

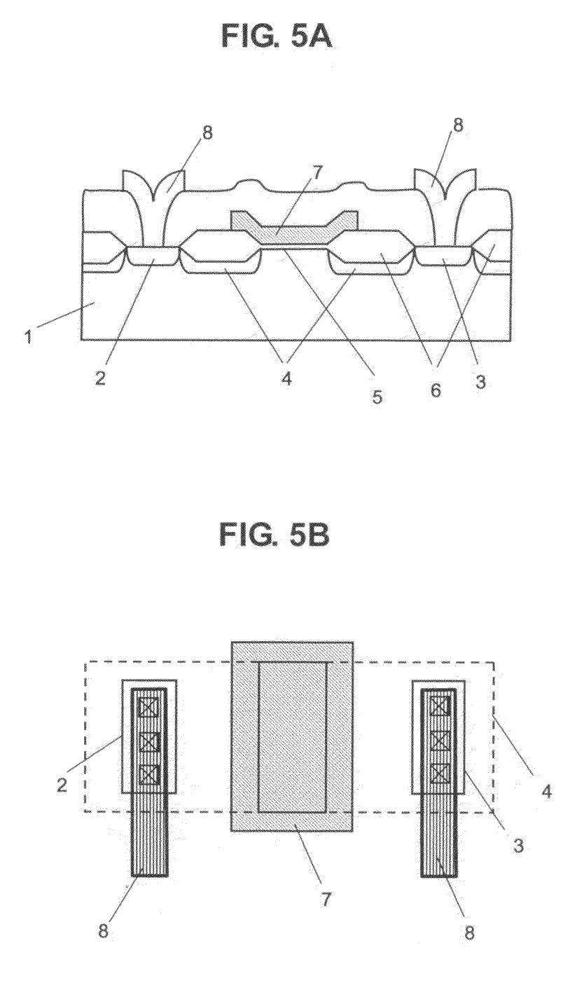

Here, for the purpose of comparison, an example of a high-voltage NMOS transistor with a conventional structure is illustrated in FIGS. 5A and 5B which are a schematic cross-sectional view and a schematic plan view thereof, respectively. In FIG. 5A, the wiring metal 8 is not laid above the boundary portions between first high impurity concentration regions and first low impurity concentration regions which serve as the source and drain regions. The wiring metal 8 may inevitably be laid above part of the boundary portion between the LOCOS oxide film 6 and the high impurity concentration region 2. However, the wiring metal 8 is not generally formed so as to overlap the boundary portions, in particular, on channel sides of the MOS transistor.

In the high-voltage NMOS transistor with the conventional structure as described above, when a drain electrode and the gate electrode are applied with a high voltage so as to perform saturation operation, a breakdown phenomenon occurs, which is different from the conventionally known avalanche breakdown (surface breakdown) caused by high electric field generated in the vicinity of the drain or parasitic bipolar breakdown which occurs when the MOS transistor operates.

For example, in the case of the parasitic bipolar breakdown, the breakdown occurs at a certain gate voltage when the gate voltage is gradually increased from a low state during the saturation operation. However, when the gate voltage is further increased, the parasitic bipolar breakdown stops occurring. This is because, when the saturation operation of the NMOS transistor is performed, a substrate current generated by impact ionization which occurs when electrons serving as channel carriers collide with Si atoms existing in the vicinity of the drain has a peak when a certain gate voltage is applied, and this phenomenon contributes to the parasitic bipolar breakdown. After passing the peak, the parasitic bipolar breakdown stops occurring.

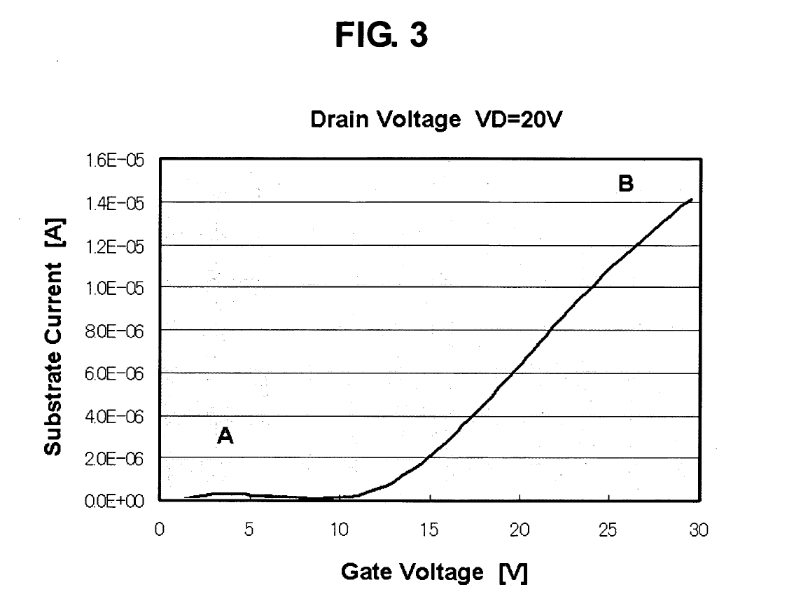

FIG. 3 illustrates a relation between the gate voltage (Vg) during a saturation operation of the general high-voltage NMOS transistor and the substrate current (Isub) generated during the operation. The substrate current once has a peak at the gate voltage as indicated by a point A of FIG. 3, and the rise in a substrate potential at this point allows the parasitic bipolar operation to easily occur. In the high-voltage NMOS transistor, however, when the gate voltage is further increased, the once decreased substrate current increases again, and hence the element breakdown occurs when a high gate voltage is applied which is accompanied by the increase of the substrate current.

This breakdown occurs due to the process described below. First, an electric field in a lateral direction is generated as the drain voltage increases in the contact portion of the drain region between the low impurity concentration region and the high impurity concentration region, making the low impurity concentration region depleted, while a depletion of the high impurity concentration region does not proceed. Accordingly, the electric field of this contact portion (boundary portion) is increased. As a result, a second impact ionization occurs to increase the substrate current, which leads to the occurrence of the second parasitic bipolar breakdown.

In this embodiment, the wiring metal connected to the drain is formed so as to be laid above the boundary portion between the low impurity concentration region and the high impurity concentration region. As a result, an electric field corresponding to the drain voltage is applied between the wiring metal and the semiconductor substrate in a depth direction (vertical direction). In this manner, an electric field concentration at the boundary portion is alleviated, and the occurrence of the second parasitic bipolar breakdown may be suppressed.

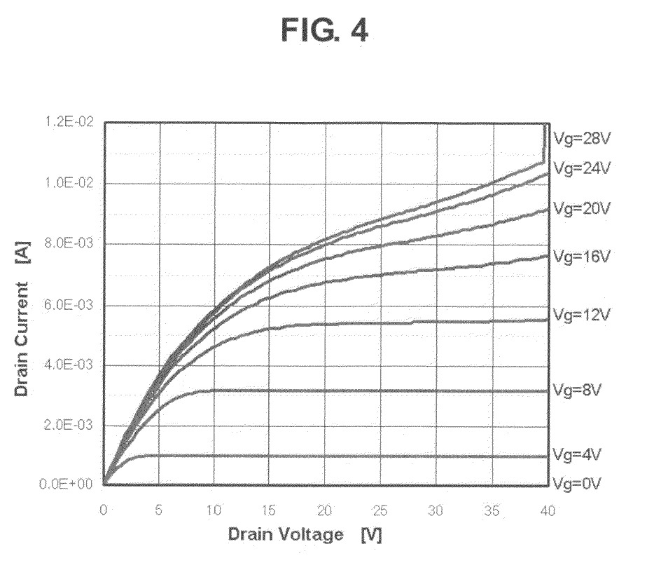

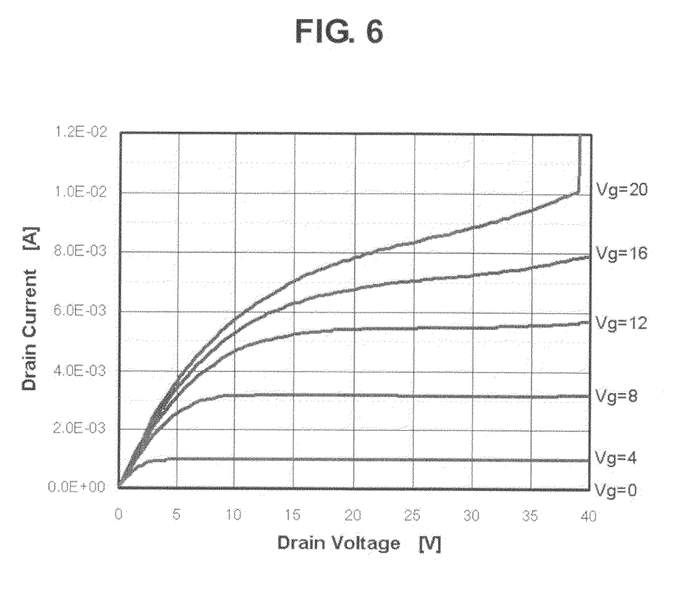

FIG. 4 illustrates drain current-drain voltage characteristics during the saturation operation of the high-voltage NMOS transistor according to this embodiment, and FIG. 6 illustrates drain current-drain voltage characteristics during the saturation operation of the high-voltage NMOS transistor with the conventional structure. It is understood from FIGS. 4 and 6 that, even though the drain breakdown both occurs at the same point of the drain voltage, the high-voltage NMOS transistor with the structure of this embodiment does not break down until applied with a gate voltage higher than the voltage at which the high-voltage NMOS transistor with the conventional structure breaks down. Note that, the overlap width of the wiring metal from the boundary portion to the low impurity concentration region may vary depending on the specification required by the element. In order to overlap the bird's beak portion of the LOCOS oxide film, the overlap width is desired to be 0.5 μm or more, and an electric field alleviation effect may be attained when the overlap width is 2 μm or less. Further, it is confirmed that the effect tends to be saturated when the overlap width is more than 2 μm.

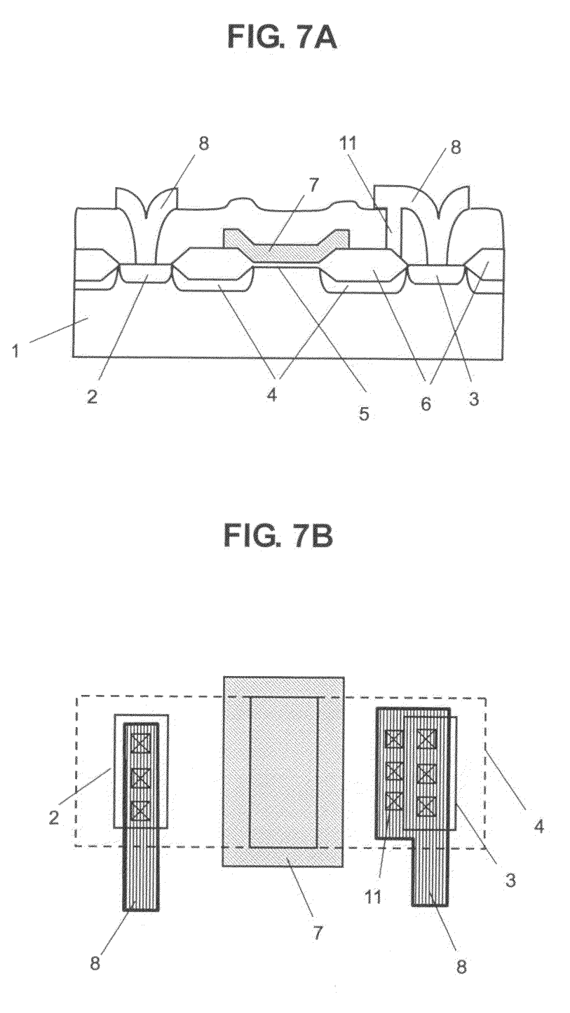

FIGS. 7A and 7B are a schematic cross-sectional view and a schematic plan view, respectively, each illustrating another aspect of the high-voltage NMOS transistor according to the present invention. In FIG. 7A, a contact hole 11 different from the contact hole in the drain region of the transistor is formed for the purpose of alleviating the electric field, and the wiring metal 8 is embedded into the contact hole 11. In this manner, the electric field in the depth direction (vertical direction) is strengthened, to thereby attain more effective electric field alleviation in the lateral direction at the boundary portion in the low impurity concentration region.

With the methods as described above, a high withstand voltage is attained in the high-voltage NMOS transistor, and the element breakdown occurring when applied with a high voltage may be suppressed, to thereby realize a reliable semiconductor device. Further, the present invention may be applied to the semiconductor device without increasing the necessary area, and without the need to add new process steps, permitting reduction in cost as well as a product turn-around-time.

What is claimed is:

1. A semiconductor device having an N-channel high-voltage metal oxide semiconductor (MOS) transistor,
the N-channel high-voltage MOS transistor comprising:
a gate insulating film disposed on a semiconductor substrate;
a gate electrode made of polysilicon disposed on the gate insulating film;
a drain region having an N-type high impurity concentration region disposed on the semiconductor substrate and apart from the gate electrode, and an N-type low impurity concentration region disposed on the semiconductor substrate and between the gate insulating film and the N-type high impurity concentration region;
an insulating film formed on the N-type low impurity concentration region and formed to be in contact with the N-type high impurity concentration region, the insulating film being thicker in thickness than the gate insulating film; and
a wiring metal thin film connected to the N-type high impurity concentration region of the drain region through a first contact hole,
wherein the wiring metal thin film is laid above a region in which the insulating film and the N-type high impurity concentration region contact with each other, and is further extended to be disposed above the N-type low impurity concentration region.

2. A semiconductor device according to claim 1, wherein:
the insulating film has a bird's beak portion in part thereof; and
the wiring metal thin film is disposed above the bird's beak portion.

3. A semiconductor device according to claim 1, wherein the wiring metal thin film is extended no less than 0.5 μm over the N-type low impurity concentration region from the region in which the insulating film and the N-type high impurity concentration region contact with each other.

4. A semiconductor device according to claim 1, wherein:
the insulating film has a bird's beak portion in part thereof; and
a second contact hole different from the first contact hole is further disposed above the bird's beak portion and filled with the wiring metal thin film.

5. A semiconductor device according to claim 2, wherein the wiring metal thin film is extended no less than 0.5 μm over the N-type low impurity concentration region from the region in which the insulating film and the N-type high impurity concentration region contact with each other.
